(19) United States
(12) Patent Application Publication
(10) Pub. No.: US 2009/0113273 A1
(43) Pub. Date: Apr. 30, 2009

(54) APPARATUS AND METHOD FOR TRANSMITTING AND RECEIVING DATA RESTORATION INFORMATION IN A COMMUNICATION SYSTEM

(75) Inventors: Yong-Seok KIM, Suwon-si (KR); Jae-Hee CHO, Seoul (KR); Kwan-Hee ROH, Hwaseong-si (KR); Soon-Young YOON, Seoul (KR); June MOON, Seoul (KR)

Correspondence Address: Jefferson IP Law, LLP, 1730 M Street, NW, Suite 807, Washington, DC, 20036, US

(73) Assignee: SAMSUNG ELECTRONICS CO. LTD., Suwon-si (KR)

(21) Appl. No.: 12/259,039

(22) Filed: Oct. 27, 2008

(30) Foreign Application Priority Data
Oct. 30, 2007 (KR) 10-2007-0109739

(51) Int. Cl. H03M 13/05; G06F 11/10

(52) U.S. Cl. 714/776; 714/E11.032

(57) ABSTRACT

An apparatus and method for transmitting data restoration information in a communication system are provided, in which a BS transmits first data in a first zone of a frame, transmits second data in a second zone of the frame, transmits first data restoration information for restoring the first data in the first zone, and transmits second data restoration information for restoring the second data in the second zone. The first data comprises the same data as data transmitted simultaneously by at least one repeater and the second data comprises data that is different from data transmitted by the at least one repeater.

### PRIORITY

This application claims the benefit under 35 U.S.C. § 119(a) of a Korean patent application filed in the Korean Intellectual Property Office on Oct. 30, 2007 and assigned Serial No. 2007-109739, the entire disclosure of which is hereby incorporated by reference.

### BACKGROUND OF THE INVENTION

1. Field of the Invention

The present invention relates to data transmission and reception in a communication system. More particularly, the present invention relates to an apparatus and method for transmitting and receiving data restoration information in a communication system using repeaters.

2. Description of the Related Art

In a typical communication system, a Base Station (BS) transmits and receives data to and from a Mobile Station (MS) via a direct link. Because the fixedness of the BS results in a shadowing area within the cell coverage area of the BS and because of changes in channel status, the communication system has limitations in efficiently providing a communication service to all areas of the cell. To address this problem, the communication system employs repeaters for amplification and coverage expansion of signals from the BS.

The use of repeaters expands cell coverage area and provides a stronger signal to an MS. In addition, by using a repeater, the BS can provide a high-speed data channel to an MS at a cell boundary that would otherwise experience a worsened channel condition because of its location at the cell boundary.

In a conventional communication system, the BS can use repeaters to transmit and receive data to and from the MS. With reference to FIG. 1, the structure of frames transmitted from a BS and again transmitted by a repeater, during repeater-aided data communication between the BS and an MS, will be described below.

FIG. 1 illustrates a frame structure for data transmission and reception in a BS and repeaters in a conventional communication system.

Referring to FIG. 1, the communication system comprises a BS, one or more MSs, and n repeaters for relaying signals between the BS and the one or more MSs.

When the BS transmits and receives data to and from an MS, each frame transmitted from the BS and the repeaters, specifically Repeater 1 to Repeater n, comprises a DownLink (DL) area and an UpLink (UL) area.

The DL area comprises a preamble, a MAP, and data bursts. The preamble delivers a synchronization signal for synchronization acquisition and the MAP comprises data restoration information for restoring the data of the data bursts. The data bursts carry the transmission data.

Upon receipt of a frame from the BS, the MS acquires synchronization to the BS using the preamble. Then the MS receives the MAP using a Frame Control Header (FCH) comprised in the frame and acquires information for restoring a DL data burst allocated to the MS using the MAP.

As illustrated in FIG. 1, the frames transmitted from the BS and the repeaters are configured to transmit the same data simultaneously.

In this context, there exists a need for developing a technique for increasing system efficiency through efficient use of resources in a system having a BS and repeaters.

### SUMMARY OF THE INVENTION

An aspect of the present invention is to address at least the above-mentioned problems and/or disadvantages and to provide at least the advantages described below. Accordingly, an aspect of the present invention is to provide an apparatus and method for transmitting and receiving data restoration information in a communication system.

Another aspect of the present invention is to provide an apparatus and method for transmitting and receiving data restoration information in a communication system using repeaters.

A further aspect of the present invention is to provide an apparatus and method for transmitting and receiving data restoration information to reduce resource consumption in a communication system using repeaters.

In accordance with an aspect of the present invention, a method for transmitting data restoration information in a BS is provided. The method comprises transmitting first data in a first zone of a frame, transmitting second data in a second zone of the frame, transmitting first data restoration information for restoring the first data in the first zone, and transmitting second data restoration information for restoring the second data in the second zone. The first data comprises the same data as data transmitted simultaneously by at least one repeater and the second data comprises data that is different from data transmitted by the at least one repeater.

In accordance with another aspect of the present invention, a method for receiving data restoration information in an MS is provided. The method comprises, detecting first data restoration information for restoring first data in a first zone of the frame when frame signal is received, detecting second data restoration information for restoring second data in a second zone of the frame, restoring the first data based on the first data restoration information, and restoring the second data based on the second data restoration information. The first data comprises the same data as data transmitted simultaneously by at least one repeater and the second data comprises data that is different from data transmitted by the at least one repeater.

In accordance with a further aspect of the present invention, an apparatus for transmitting data restoration information in a communication system is provided. The apparatus comprises a BS for transmitting first data in a first zone of a frame, for transmitting second data in a second zone of the frame, for transmitting first data restoration information for restoring the first data in the first zone, and for transmitting second data restoration information for restoring the second data in the second zone. The first data comprises the same data as data transmitted simultaneously by at least one repeater and the second data comprises data that is different from data transmitted by the at least one repeater.

In accordance with still another aspect of the present invention, an apparatus for receiving data restoration information in a communication system is provided. The apparatus includes an MS for detecting first data restoration information for restoring first data in a first zone of the frame when frame signal is received, for detecting second data restoration information for restoring second data in a second zone of the frame, for restoring the first data based on the first data restoration information, and for restoring the second data based on the second data restoration information. The first data is the same data as data transmitted simultaneously by at least one repeater and the second data comprises data that is different from data transmitted by the at least one repeater.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features and advantages of certain exemplary embodiments of the present invention will be more apparent from the following description taken in conjunction with the accompanying drawings, in which:

FIG. 1 illustrates a frame structure for data transmission and reception in a BS and repeaters in a conventional communication system;

FIG. 2 illustrates a configuration of a communication system according to an exemplary embodiment of the present invention;

FIG. 3 illustrates a frame structure including a MAP in a communication system according to an exemplary embodiment of the present invention;

FIGS. 4A and 4B illustrate frame structures each carrying a submap in a communication system according to exemplary embodiments of the present invention; and

FIG. 5 illustrates a frame structure carrying MAPs on a zone basis in a communication system according to an exemplary embodiment of the present invention.

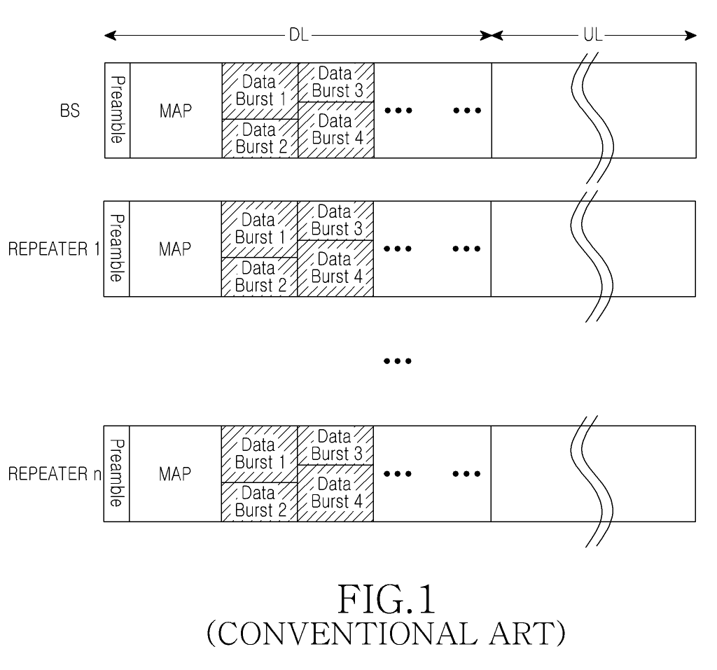

Throughout the drawings, the same drawing reference numerals will be understood to refer to the same elements, features and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It comprises various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

Exemplary embodiments of the present invention provide an apparatus and method for transmitting and receiving data restoration information in a communication system, for example, a communication system using repeaters. In accordance with exemplary embodiments of the present invention, a BS and at least one repeater associated with the BS transmit data in separate zones of a frame depending on whether the data are the same or different. While the following description is made in the context of a repeater that relays a signal from the BS, this is merely for the sake of convenience and it is to be clearly understood that the present invention is also applicable to other devices and methods for relaying signals from a BS. Furthermore, for sake of convenience, a BS and a repeater are referred to as a macro BS and a micro-zone repeater, respectively.

In the following description of exemplary embodiments of the present invention, the term “macro zone” refers to an area in which a macro BS and micro-zone repeaters can transmit the same data simultaneously and the term “micro zone” refers to an area in which the macro BS and the micro-zone repeaters can transmit the same or different data simultaneously.

A micro zone may comprise an area in which the macro BS and a micro-zone repeater can transmit data to a particular MS in cooperation. Therefore, the macro BS and the micro-zone repeaters can transmit the same or different data to the MS in cooperation.

The micro zone is divided into at least two areas. In a first area, the macro BS and the micro-zone repeaters transmit different data. In the second area, the macro BS and the micro-zone repeaters transmit the same data.

In an exemplary embodiment, a transmission frame can be divided into a zone in which the macro BS and the micro-zone repeaters transmit different data and a zone in which they transmit the same data in cooperation.

When a space between the macro BS and the micro-zone repeaters is greater than a threshold distance or farther, signal interference decreases among them. In that case, the macro BS and the micro-zone repeaters can transmit different data. The same concept can apply when signal interference decreases among the macro BS and the micro-zone repeaters by use of beamforming, space division, code division, power control, etc.

If the micro-zone repeaters are to transmit different data, each frame from the macro BS and the micro-zone repeaters (i.e. Repeater 1 to Repeater n) can comprise a plurality of data bursts. Accordingly, when the micro-zone repeaters transmit different data, more data bursts can be transmitted in one frame.

When more data bursts are transmitted in one frame, the amount of information necessary for data burst restoration in a MAP also increases. That is, the MAP carries the data restoration information for the data bursts in the frame. However, because the MAP information increases with the increased number of data bursts, frames transmitted from the macro BS and the micro-zone repeaters may suffer from MAP transmission-caused resource dissipation. In this context, exemplary embodiments of the present invention provide a technique for transmitting and receiving a MAP, i.e. data restoration information.

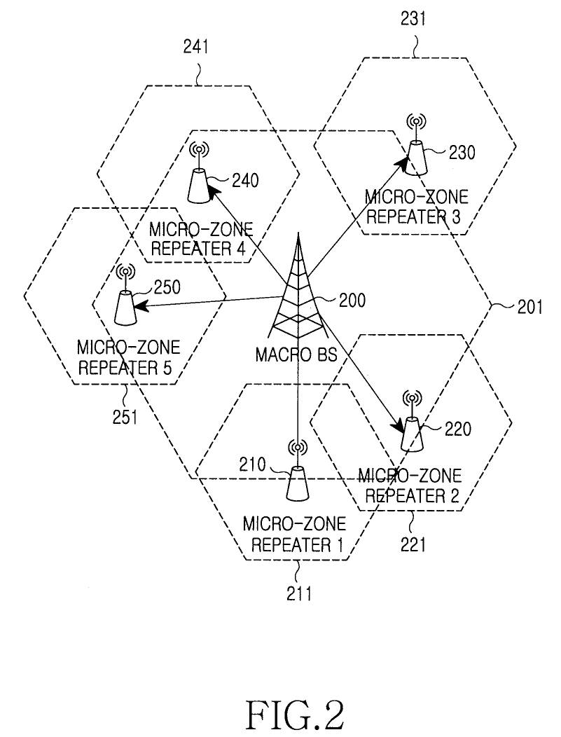

FIG. 2 illustrates a configuration of a communication system according to an exemplary embodiment of the present invention.

Referring to FIG. 2, the communication system comprises a macro BS 200 and a plurality of (first to fifth) micro-zone repeaters 210, 220, 230, 240 and 250 connected to the macro BS 200. The macro BS 200 covers a macro cell 201 and the first to fifth micro-zone repeaters 210, 220, 230, 240 and 250 cover first to fifth micro cells 211, 221, 231, 241 and 251, respectively.

The macro BS 200 and the micro-zone repeaters 210, 220, 230, 240 and 250 each can use a single antenna or multiple antennas. Also, the macro BS 200 and the micro-zone repeaters 210, 220, 230, 240 and 250 can operate in Time Division Multiplexing (TDM) or Code Division Multiplexing (CDM), or in both.

The macro BS 200 divides a transmission frame into a macro zone, in which the macro BS 200 and the micro-zone repeaters 210, 220, 230, 240 and 250 transmit the same data and a micro zone, in which they may transmit different data. The macro zone and the micro zone are determined by the macro BS 200 depending on system situations or setting, for example.

The macro BS 200 is able to control such that the macro BS 200 and the micro-zone repeaters 210, 220, 230, 240 and 250 may transmit transmission data discriminately in each frame.

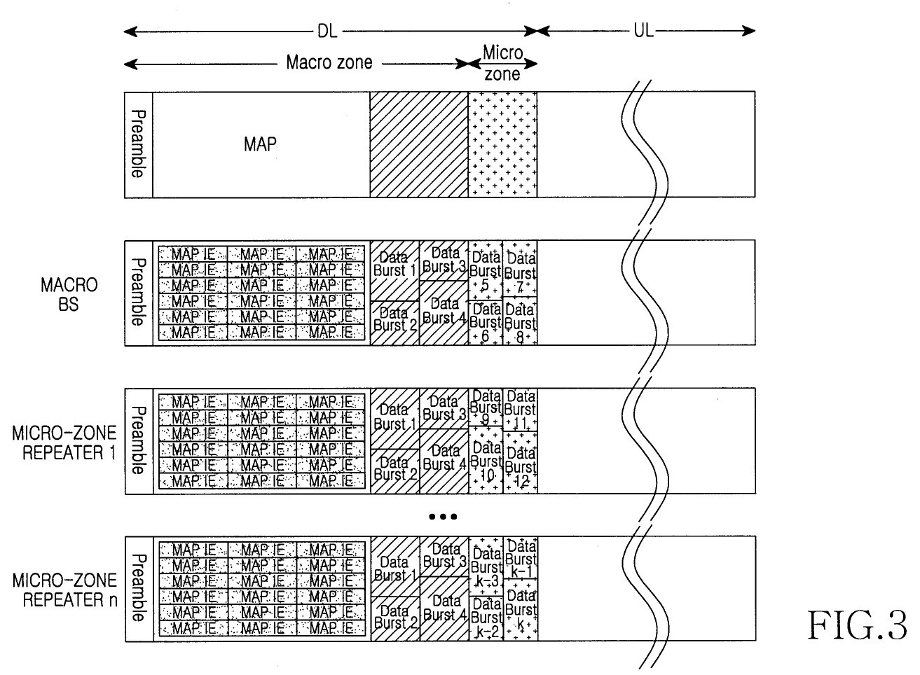

Now a frame structure including a MAP that carries data restoration information, for transmission from the macro BS and the micro-zone repeaters will be described with reference to FIG. 3.

FIG. 3 illustrates a frame structure including a MAP in a communication system according to an exemplary embodiment of the present invention.

Referring to FIG. 3, the frame structure is for frames transmitted from the macro BS and the micro-zone repeaters. Each of the frames comprise a DL area and a UL area. The DL area comprises a macro zone and a micro zone. The macro zone comprises a preamble, a MAP, and data regions, for example, wherein the data region may comprise data bursts therein. The micro zone has a data region for transmitting data bursts.

Herein, the macro BS and the micro-zone repeaters use a TDM frame that is divided in time, by way of example. Of course, it can be further contemplated that the frame uses an FDM that is divided in frequency.

In the macro zone, the macro BS and the micro-zone repeaters transmit the same first to fourth data bursts. However, in the micro zone, the macro BS transmits fifth to eighth data bursts, a first micro-zone repeater transmits ninth to twelfth data bursts, and an n^{th} micro-zone repeater transmits (k-3)^{th} to k^{th} data bursts.

The frame comprises a MAP region in the macro zone that carries data restoration information for restoring the first to k^{th} data bursts of the macro zone and the micro zone in the macro zone.

As the number of micro-zone repeaters increases, the number of data bursts to be transmitted in the frames of the macro BS and the micro-zone repeaters also increases. Consequently, the MAP should carry more data restoration information about the data bursts.

However, because the MAP carries more information, it occupies more space and thus less area is available for the data bursts in the frame.

In accordance with an exemplary embodiment of the present invention, MAPs for data bursts transmitted in the micro zones of the frames from the macro BS and the micro-zone repeaters are comprised in the micro zones in order to more efficiently use resources.

The macro BS generates the micro-zone MAPs for data bursts transmitted from the micro-zone repeaters associated with the macro BS and transmits them in the micro zones of the frames transmitted from the micro-zone repeaters. That is, when the micro-zone repeaters transmit different data, they transmit different MAP information in the micro-zone MAPs.

The macro BS can transmit MAP restoration information for restoring the MAPs of the micro zones in the MAPs of the macro zones. The macro BS can transmit at least one piece of information required for restoring the MAPs of the micro zones.

To transmit the MAP in the micro zone, the macro BS can transmit information required to restore the MAPs of the macro zone and the micro zone preliminarily or in an FCH.

An MS that receives data from the macro BS and the micro-zone repeaters.

The MS acquires synchronization to the macro BS using the preamble of the frame. The MS then acquires information required for MAP restoration in the FCH of the frame.

If the FCH comprises MAP restoration information for restoring the MAPs of the macro zone and the micro zone, the MS receives the MAPs in the macro zone and the micro zone using the FCH and restores data bursts allocated to the MS using the MAPs.

If the MAP of the macro zone comprises MAP restoration information for restoring the MAP of the micro zone, the MS restores the MAP of the micro zone based on the MAP of the macro zone and restores data bursts of the micro zone using the MAP of the micro zone.

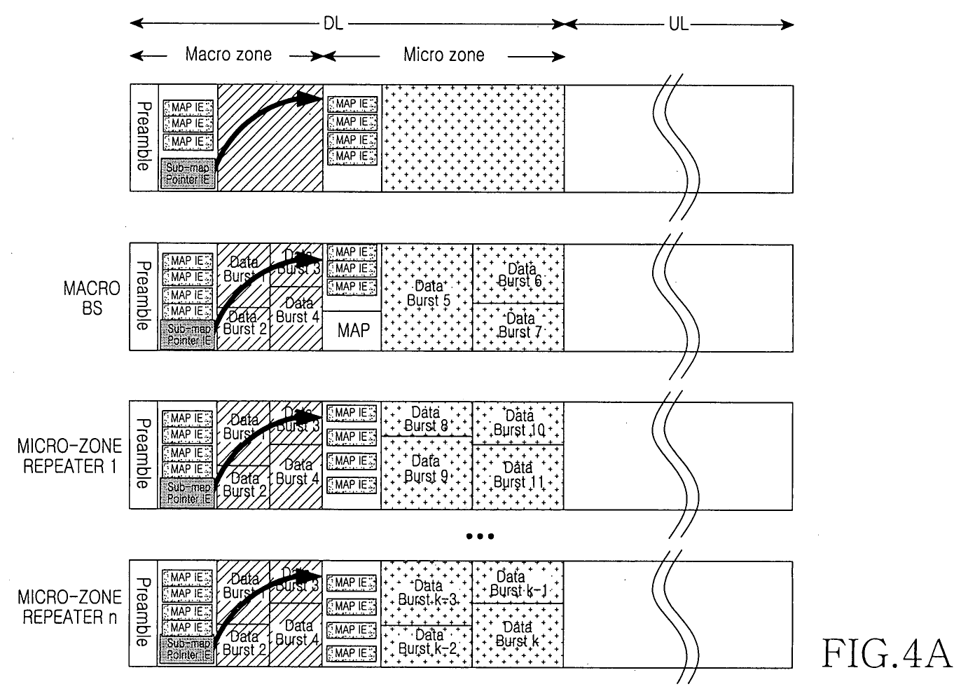

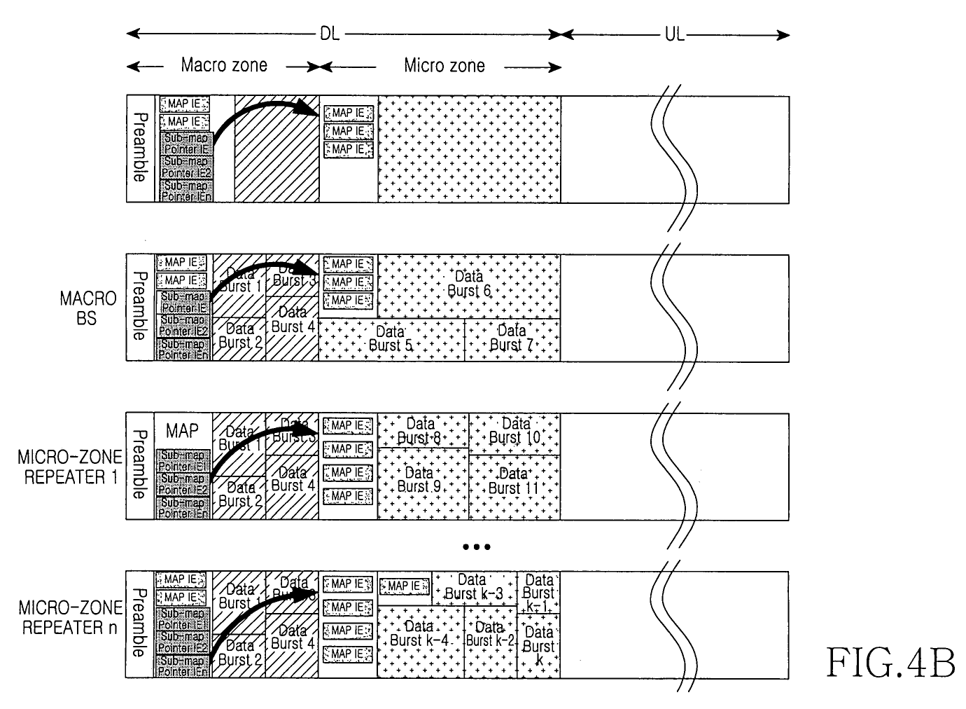

When data restoration information is transmitted in the frames of the macro BS and the micro-zone repeaters, MAP restoration information for detecting the MAP of the micro zone can be transmitted in the macro zone. The MAP comprised in the micro zone is referred to as a submap. With reference to FIGS. 4A and 4B, exemplary frame structures each including a submap will be described below.

FIG. 4A illustrates a frame structure having a submap in a communication system according to an exemplary embodiment of the present invention.

Referring to FIG. 4A, the frame structure is used for the macro BS and the micro-zone repeaters. Each of the frames comprises a DL area and a UL area. The DL area comprises a macro zone and a micro zone. The macro zone comprises a preamble, a MAP, and data bursts and the micro zone comprises data bursts.

In the macro zone, the macro BS and the micro-zone repeaters transmit the same first to fourth data bursts. In the micro zone, the macro BS transmits fifth, sixth and seventh data bursts, the first micro-zone repeater transmits eighth to eleventh data bursts, and the n^{th} micro-zone repeater transmits (k-3)^{th} to k^{th} data bursts.

The DL area comprises MAPs in the macro zone and the micro zone. The MAP of the macro zone is used for restoring data bursts transmitted in the macro zone and the MAP of the micro zone is used for restoring data bursts transmitted in the micro zone.

The MAP of the macro zone comprises a plurality of MAP Information Elements (TEs) by which to restore the first to fourth data bursts.

A submap pointer IE comprised in the macro zone provides information for detecting the MAP of the micro zone, i.e. the submap. The submap detection information indicates the start position of the micro zone, for example. It is assumed that the size of the submap is equal for the macro BS and every micro-zone repeater and the submap is positioned at the start of the micro zone. Therefore, since the start of the micro zone is indicated by the submap pointer IE, there is no need for a further operation or additional information for identifying the micro zone.

The submaps of the frames from the macro BS and the micro-zone repeaters comprise different MAP TEs. The submap of the macro BS comprises MAP TEs for restoring the fifth, sixth and seventh data bursts whereas the submap of the first micro-zone repeater comprises MAP TEs for restoring the eighth to eleventh data bursts. The submap of the n^{th} micro-zone repeater comprises MAP TEs for restoring the (k-3)^{th} to k^{th} data bursts.

Although each submap carries different information, the submaps are of the same size. In this case, the macro BS sets the largest of submap sizes required in the micro zones of the micro-zone repeaters as the submap size.

In this submap transmission scheme, when a small amount of data is transmitted in data bursts of a micro zone, a submap may have an extra area that does not comprise MAP TEs.

In the illustrated case of FIG. 4A, a single submap pointer IE is used. With reference to FIG. 4B, use of a plurality of submap pointer TEs will be described below.

FIG. 4B illustrates a frame structure using a submap in a communication system according to an exemplary embodiment of the present invention.

Referring to FIG. 4B, the frame structure applies to frames from the macro BS and the micro-zone repeaters. Each of the frames comprises a DL area and a UL area. The DL area comprises a macro zone and a micro zone. The macro zone comprises a preamble, a MAP, and data bursts and the micro zone comprises data bursts.

Hence, in the macro zone, the macro BS and the micro-zone repeaters transmit the same first to fourth data bursts. Meanwhile, in the micro zone, the macro BS transmits fifth, sixth and seventh data bursts, the first micro-zone repeater transmits eighth to eleventh data bursts, and the n^{th} micro-zone repeater transmits (k-3)^{th} to k^{th} data bursts.

The DL area comprises MAPs in the macro zone and the micro zone. The MAP of the macro zone is used for restoring data bursts transmitted in the macro zone and the MAP of the micro zone is used for restoring data bursts transmitted in the micro zone.

The MAP of the macro zone comprises a plurality of MAP IEs by which to restore the first to fourth data bursts.

A plurality of submap pointer IEs comprised in the macro zone provide information for detecting the MAP of the micro zone, i.e. the submap. The submap IEs comprise different information and each submap pointer IE indicates the start of a micro zone of the macro BS or a micro-zone repeater corresponding to the submap.

In an exemplary implementation, the submap is positioned at the start of the micro zone. Therefore, since the start of the micro zone is indicated by the submap pointer IE, there is no need for a further operation for identifying the micro zone for each of the macro BS and the micro-zone repeaters. Of course, the micro zone may start at a different position for each of the macro BS and the micro-zone repeaters.

The submaps comprise different MAP IEs. The submap of the macro BS comprises MAP IEs for restoring the fifth, sixth and seventh data bursts, and the submap of the first micro-zone repeater comprises MAP IEs for restoring the eighth to eleventh data bursts. The submap of the n^{th} micro-zone repeater comprises MAP IEs for restoring the (k-3)^{th} to k^{th} data bursts.

Hence, each submap carries different information and the MAP of the macro zone comprises a plurality of submap pointer IEs for detecting the submaps.

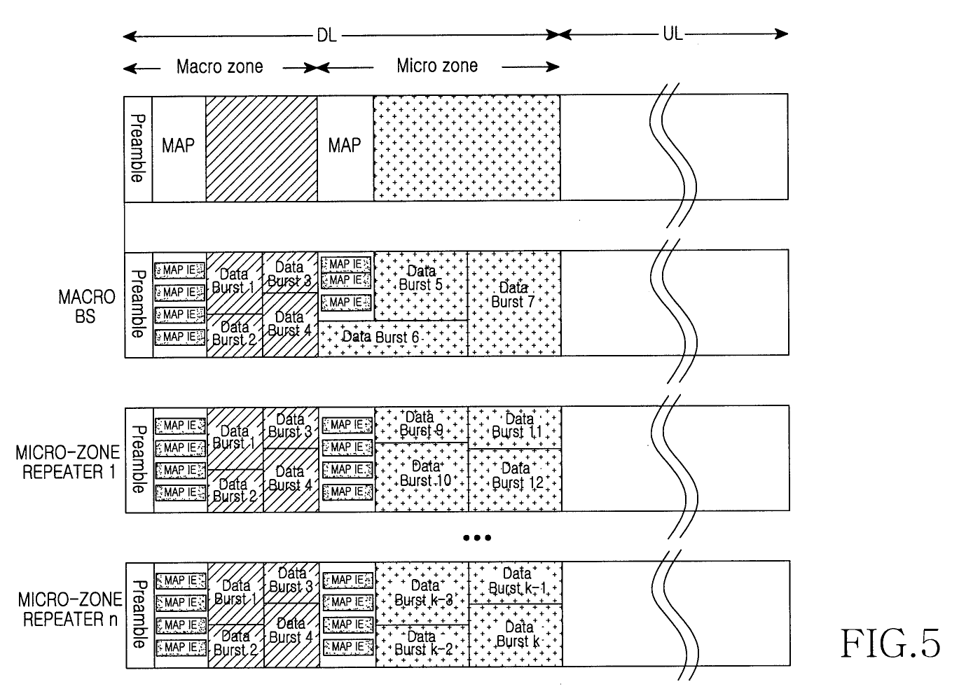

The macro BS can make a choice between the submap pointer IE-based submap detection schemes illustrated in FIGS. 4A and 4B. With reference to FIG. 5, independent use of the MAP of the micro zone without receiving the MAP of the macro zone will be described below.

FIG. 5 illustrates a frame structure having MAPs on a zone basis in a communication system according to an exemplary embodiment of the present invention.

Referring to FIG. 5, the frame structure applies for frames from the macro BS and the micro-zone repeaters. The frame comprises a DL area and a UL area. The DL area comprises a macro zone and a micro zone. The macro zone comprises a preamble, a MAP, and data bursts and the micro zone comprises data bursts.

In the macro zone, the macro BS and the micro-zone repeaters transmit the same first to fourth data bursts. In the micro zone, the macro BS transmits fifth, sixth and seventh data bursts, the first micro-zone repeater transmits eighth to eleventh data bursts, and the n^{th} micro-zone repeater transmits (k-3)^{th} to k^{th} data bursts.

The DL area comprises MAPs in the macro zone and the micro zone. The MAP of the macro zone is used for restoring data bursts transmitted in the macro zone and the MAP of the micro zone is used for restoring data bursts transmitted in the micro zone.

The MAP of the macro zone comprises a plurality of MAP IEs by which to restore the first to fourth data bursts.

Each of the MAPs in the micro zones comprises different MAP IEs. The MAP of the macro BS comprises MAP IEs for restoring the fifth, sixth and seventh data bursts, and the MAP of the first micro-zone repeater comprises MAP IEs for restoring the eighth to eleventh data bursts. The MAP of the n^{th} micro-zone repeater comprises MAP IEs for restoring the (k-3)^{th} to k^{th} data bursts.

The MAP can be transmitted in the micro zone in various manners. For example, information required for restoring the MAPs of the macro zone and the micro zone can be transmitted to MSs in an FCH or by an upper-layer message.

As is apparent from the above description, exemplary embodiments of the present invention configure data restoration information about data in a different manner according to a frame area carrying the data. Since a frame is divided into a macro zone and a micro zone and information required for restoring data bursts transmitted in the macro zone and the micro zone are distributed for transmission in the frame, the resulting decrease of MAP transmission overhead saves resources. Also, the data restoration information transmission/reception method of the present invention increases system performance during data transmission and reception in a communication system using micro-zone repeaters.

While the invention has been shown and described with reference to certain exemplary embodiments thereof, it will be understood by those skilled in the art that various changes in form and details may be made therein without departing from the spirit and scope of the present invention as defined by the appended claims and their equivalents.

What is claimed is:

1. A method for transmitting data restoration information in a Base Station (BS), the method comprising:
transmitting first data in a first zone of a frame;
transmitting second data in a second zone of the frame;
transmitting first data restoration information for restoring the first data in the first zone; and
transmitting second data restoration information for restoring the second data in the second zone,
wherein the first data comprises the same data as data transmitted simultaneously by at least one repeater and the second data comprises data that is different from data transmitted by the at least one repeater.

2. The method of claim 1, wherein each of the first data restoration information and the second data restoration information comprises a MAP.

3. The method of claim 1, further comprising transmitting at least one piece of information required for detecting the second data restoration information in the first zone.

4. The method of claim 3, wherein the at least one piece of information indicates a start of the second zone.

5. The method of claim 1, further comprising transmitting information required for detecting the second data restoration information in a Frame Control Header (FCH) of the frame.

6. A method for receiving data restoration information in a Mobile Station (MS), the method comprising:
detecting first data restoration information for restoring first data in a first zone of a frame when frame signal is received;
detecting second data restoration information for restoring second data in a second zone of the frame;
restoring the first data based on the first data restoration information; and
restoring the second data based on the second data restoration information,
wherein the first data comprises the same data as data transmitted simultaneously by at least one repeater and the second data comprises data that is different from data transmitted by the at least one repeater.

7. The method of claim 6, wherein each of the first data restoration information and the second data restoration information comprises a MAP.

8. The method of claim 6, further comprising receiving at least one piece of information required for detecting the second data restoration information in the first zone.

9. The method of claim 8, wherein the at least one piece of information indicates a start of the second zone.

10. The method of claim 6, further comprising receiving information required for detecting the second data restoration information in a Frame Control Header (FCH) of the frame.

11. An apparatus for transmitting data restoration information in a communication system, the apparatus comprising:
a Base Station (BS) for transmitting first data in a first zone of a frame, for transmitting second data in a second zone of the frame, for transmitting first data restoration information for restoring the first data in the first zone, and for transmitting second data restoration information for restoring the second data in the second zone,
wherein the first data comprises the same data as data transmitted simultaneously by at least one repeater and the second data comprises data that is different from data transmitted by the at least one repeater.

12. The apparatus of claim 11, wherein each of the first data restoration information and the second data restoration information comprises a MAP.

13. The apparatus of claim 11, wherein the BS transmits at least one piece of information required for detecting the second data restoration information in the first zone.

14. The apparatus of claim 13, wherein the at least one piece of information indicates a start of the second zone.

15. The apparatus of claim 13, wherein the BS transmits information required for detecting the second data restoration information in a Frame Control Header (FCH) of the frame.

16. An apparatus for receiving data restoration information in a communication system, the apparatus comprising:
a Mobile Station (MS) for detecting first data restoration information for restoring first data in a first zone of a frame when frame signal is received, for detecting second data restoration information for restoring second data in a second zone of the frame, for restoring the first data based on the first data restoration information, and for restoring the second data based on the second data restoration information,
wherein the first data comprises the same data as data transmitted simultaneously by at least one repeater and the second data comprises data that is different from data transmitted by the at least one repeater.

17. The apparatus of claim 16, wherein each of the first data restoration information and the second data restoration information comprises a MAP.

18. The apparatus of claim 16, wherein the MS receives at least one piece of information required for detecting the second data restoration information in the first zone.

19. The apparatus of claim 18, wherein the at least one piece of information indicates a start of the second zone.

20. The apparatus of claim 16, wherein the MS receives information required for detecting the second data restoration information in a Frame Control Header (FCH) of the frame.
